(19) United States
(12) Patent Application Publication
(10) Pub. No.: US 2011/0200939 A1
(43) Pub. Date: Aug. 18, 2011

(54) POLYAMIC ACID, POLYIMIDE, PHOTOSENSITIVE RESIN COMPOSITION COMPRISING THE SAME AND DRY FILM MANUFACTURED BY THE SAME

(75) Inventors: Kwang-Joo LEE, Daejeon (KR); You-Jin KYUNG, Daejeon (KR); Joo-Eun KO, Daejeon (KR); Heon-Sik SONG, Daejeon (KR); Jung-Jin SHIM, Pohang-si (KR); Hee-Jung KIM, Daejeon (KR)

(73) Assignee: LG CHEM, LTD., Seoul (KR)

(21) Appl. No.: 12/870,118

(22) Filed: Aug. 27, 2010

(30) Foreign Application Priority Data
Aug. 28, 2009 (KR) 10-2009-0080606
May 18, 2010 (KR) 10-2010-0046602

(51) Int. Cl. G03F 7/004; C08F 22/38; C08F 26/06

(52) U.S. Cl. 430/280.1; 430/283.1; 526/304; 526/259

(57) ABSTRACT

The present invention relates to a polyamic acid or polyimide comprising a heat-polymerizable or photo-polymerizable functional group, a photosensitive resin composition comprising the polyamic acid or the polyimide, a photosensitive resin composition being capable of providing a cured film that can be used for patterning at a high resolution and that has an excellent developing property in an alkaline aqueous solution, flexibility, adhesion strength, resistance to welding heat, and pressure cooker test (PCT) resistance, and a dry film prepared from the composition.

### TECHNICAL FIELD

The present invention relates to a new polyamic acid, polyimide, a photosensitive resin composition comprising the polyamic acid or polyimide and a dry film prepared therefrom. More specifically, the present invention relates to a new polyamic acid or polyimide containing a functional group having a thermal polymerization or photopolymerization property; a photosensitive resin composition capable of forming a pattern with a high resolution, an excellent development property by an alkalin aqueous solution, flexibility, adhesiveness, soldering heat resistance, and Pressure Cooker Test (PCT) resistance; an a dry film manufactured therefrom.

The present application claims priority to and the benefit of Korean patent applications No. 10-2009-0080606 filed in the Korea Intellectual Property Office on Aug. 28, 2009 and to Korean patent application No. 10-2010-0046602 filed in the Korea Intellectual Property Office on May 18, 2010, the entire contents of which are incorporated herein by reference.

### BACKGROUND ART

Since polyimide and a precursor thereof have excellent durability, heat resistance, flame retardancy, and mechanical and electronic properties, they are actively used as a base film of a printed circuit board, and a highly integrated semiconductor device or a cover film for a highly integrated multilayered wiring board.

Recently, electronic devices have become compact and multifunctional, and particularly, cellular phones become to have a thin and light weight and to be simple. As a high-density interconnect design and fine circuit pattern have been applied to the circuit board used in electronic devices, a photosensitive resin composition capable of improving fineness and precise registration of a circuit pattern using photolithography has been suggested instead of a conventional polyimide cover layer film The photosensitive resin composition needs to be developed in a weak alkaline aqueous solution for safety during a development processing.

The photosensitive resin composition used for a conventional dry film and the like has been obtained by adding an acrylate to an epoxy resin. However, such resin composition has poor flame retardancy and can be discolored during soldering due to low soldering heat resistance of cured resin or causes delamination from the circuit. Additionally, the resin composition is not suitable for a protective film of the circuit board because its insufficient flexibility and bending resistance cause cracks during repeated foldings

To solve these problems, there has been a need for developing a photosensitive resin for protecting a circuit, which comprises polyimide as a main component and which has high heat resistance, bending resistance, and a good dielectric property (JP 2001-00357436, JP 2003-287886). To achieve processability at a low temperature, a monomer having a low transition temperature (Tg) was used. To overcome warpage that occurs after curing or soldering due to thermal mismatch, a photosensitive resin composition for reducing the modulus was suggested (JP 2003-140339). Vacuum lamination is applied for filling an uneven ( [symbol] ) pattern at a low temperature of 70 to 80° C., and a crosslinker being capable of easily performing vacuum lamination is added to a photosensitive resin composition. When the films prepared from the previous photosensitive resin compositions or from the cured products is used for a circuit protective film, however the cured film has good flexibility, but insufficient adhesion strength to the support, resistance to welding heat, and pressure cooker test (PCT) resistance, compared to a circuit protective made from an epoxy-based material used in the prior art. Thus, there is a limit in commercialization of such films.

### DISCLOSURE OF INVENTION

### Technical Problems

One embodiment of the present invention is for providing a novel polyamic acid.

In addition, another embodiment of the present invention is for providing a novel polyimide.

Another embodiment of the present invention is for providing a photosensitive resin composition for producing a cured coating that is capable of forming a pattern with high resolution, an excellent development property in an alkaline aqueous solution, and excellent flexibility, adhesiveness, soldering heat resistance and pressure cooker test (PCT) resistance.

Further embodiment of the present invention is for providing a dry film prepared from the photosensitive resin composition.

### Technical Solutions

One embodiment of the present invention provides a polyamic acid comprising a specific repeating unit .

Another embodiment of the present invention provides a polyimide comprising a specific repeating unit.

A further embodiment of the present invention provides a photosensitive resin composition comprising at least one polymer resin selected from the group consisting of the polyamic acid and the polyimide; a curing accelerator; a photocrosslinker; and a photoinitiator.

Another embodiment of the present invention provides a dry film comprising the photosensitive resin composition.

Another embodiment of the present invention provides a circuit board manufactured by using the dry film.

In addition, another embodiment of the present invention provides a laminated body for a semiconductor.

Hereinafter, according to embodiments of the present invention, a polyamic acid, a polyimide, a photosensitive resin composition comprising the polyamic acid, or the polyimide, and a dry film comprising the photosensitive resin composition will be described in more detail.

In accordance with an embodiment of the present invention, a polyamic acid comprising a repeating unit represented by Chemical Formula 1 is provided.

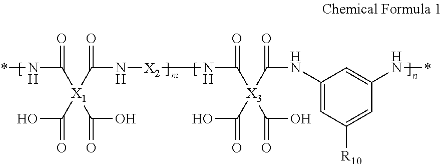

In Chemical Formula 1, n is from 5 mol % or more to less than 70 mol %, m is from 30 mol % or more to less than 95 mol %, n+m is 100 mol %, X₁ and X₃ are the same or different and are independently a tetravalent organic group comprising an aromatic ring structure, X₂ is a divalent organic group comprising an aromatic ring structure, and R₀ is a functional group selected from the group consisting of functional groups represented by Chemical Formula 21 to 30.

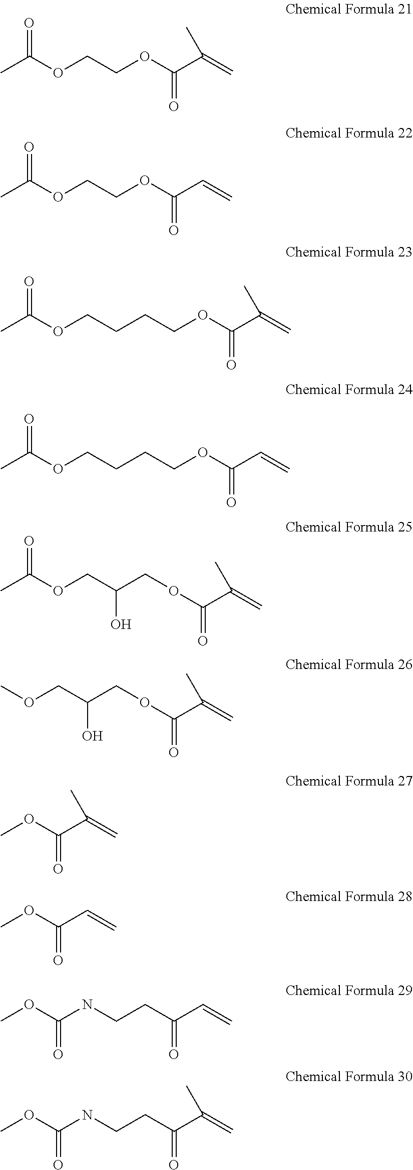

The present inventors completed the present invention based on the finding that using a polyamic acid or polyimide introduced with a functional group selected from the group consisting of the functional groups represented by Chemical Formula 21 to 30 made it possible to provide a cured film capable of forming a pattern with high resolution and having an excellent developing property in an alkaline aqueous solution, excellent flexibility, excellent adhesion strength, resistance to welding heat, and excellent resistance in a pressure cooker test (PCT) resistance.

In particular, the functional group selected from the group consisting of the functional groups represented by Chemical Formula 21 to 30, is capable of photo-curing, and thus can react with a photocrosslinker to produce a covalent bond, thereby increasing the physiochemical properties such as heat resistance of a cured film.

Meanwhile, in Chemical Formula 1, X₁ and X₃ are the same or different, and are independently a tetravalent organic group comprising a group represented by Chemical Formula 31 or 32.

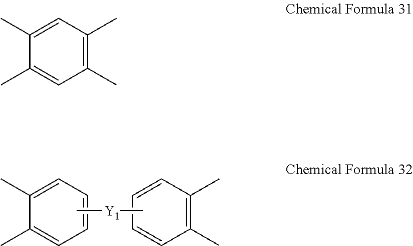

In Chemical Formula 32, Y₁ is a single bond, —O—, —CO—, —S—, —SO₂—, —C(CH₃)₂—, —C(CF₃)₂—, —CONH, —(CH₂)n₁-, —O(CH₂)n₂O—, or —COO(CH₂)n₃OCO—, and n₁, n₂, and n₃ are independently an integer of 1 to 5.

X₂ in Chemical Formula 1 is a divalent organic group selected from the group consisting of organic groups represented by Chemical Formula 33 to 36.

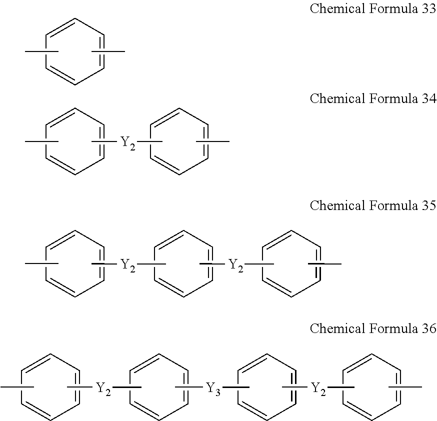

In Chemical Formula 34 to 36, Y₂ and Y₃ are the same or different, and are independently a single bond, —O—, —CO—, —S—, —SO₂—, —C(CH₃)₂—, —C(CF₃)₂—, —CONH, —(CH₂)n₁-, —O(CH₂)n₂O—, or —COO(CH₂)n₃OCO—, and n₁, n₂, and n₃ are independently an integer of 1 to 5.

According to another embodiment, a polyimide comprising a repeating unit represented by Chemical Formula 2 is provided.

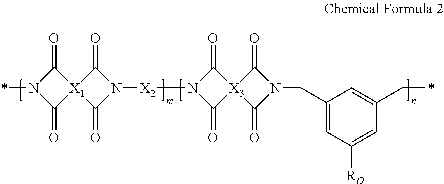

In Chemical Formula 2, X₁, X₂, X₃, R₀, m, and n are the same as defined in Chemical Formula 1.

The polyimide comprising a repeating unit represented by Chemical Formula 2 can be prepared by performing an imidization reaction of the polyamic acid comprising a repeating unit represented by Chemical Formula 1.

Examples of imidization of polyamic acid are chemical imidization in which acetic acid anhydride and pyrimidine are added to a polyamic acid solution and then heated to 50 to 100° C., or thermal imidization in which a polyamic acid solution is coated on a substrate and is then put in a oven or on a hot plate at 100 to 250° C., but are not limited thereto.

The number average molecular weight (Mn) of the polyamic acid or polyimide is preferably in the range of 5,000 to 300,000, and more preferably 8,000 to 20,000. If Mn is less than 5000, the photosensitive resin composition comprising the polyamic acid or polyimide shows a poor coating property due to low viscosity. In addition, if Mn is more than 300,000, it is difficult to process the photosensitive resin composition due to its excessively high viscosity of.

The polyamic acid comprising a repeating unit represented by Chemical Formula 1 or the polyimide comprising a repeating unit represented by Chemical Formula 2 can be prepared from a diamine compound represented by Chemical Formula 3, a diamine compound represented by Chemical Formula 4, and an acid dianhydride represented by Chemical Formula 5 or 6.

H₂N—X₂—NH₂ Chemical Formula 3

In Chemical Formula 3, X₂ is the same as defined in Chemical Formula 1.

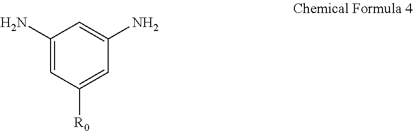

In Chemical Formula 4, R₀ is the same as defined in Chemical Formula 1.

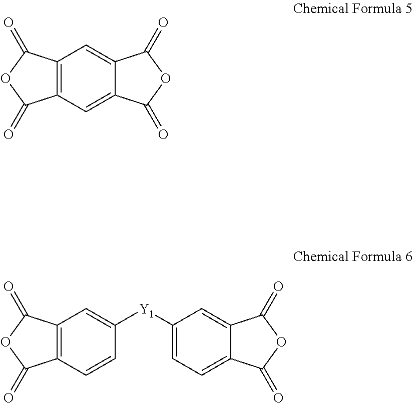

In Chemical Formula 6, Y₁ is as defined as above.

The specific examples of the diamine compounds represented by Chemical Formula 3 can be p-phenylenediamine (p-PDA), m-phenylenediamine (m-PDA), 4,4′-oxydianiline(4,4′-ODA), 3,4′-oxydianiline (3,4′-ODA), 2,2-bis-(4-[4-aminophenoxy]-phenyl)propane (BAPP), 1,3-bis-(4-aminophenoxy)benzene (TPE-R), 1,4-bis-(4-aminophenoxy)benzene (TPE-Q), 2,2-bis-(4-[3-aminophenoxy]phenyl)sulfone (m-BAPS) and the like, but the examples are not limited thereto.

Specific examples of the diamine compounds represented by Chemical Formula 4 may be 2′-(methacrylooxy)ethyl 3,5-diaminobezoate and the like, but examples are not limited thereto.

Examples of the acid dianhydrides represented Chemical Formula 5 or 6 are pyromelitic dianhydride, 3,3′-4,4′-biphenyltetracarboxylic dianhydride, 3,3′,4,4′-benzophenone tetracarboxylic dianhydride, 4,4′-oxydiphthalic anhydride, 4,4′-(4,4′-isopropylbiphenoxy)biphthalic anhydride, 2,2′-bis-(3,4-dicarboxylphenyl)hexafluoropropane dianhydride, ethylene glycol bis-(anhydro-trimellitate (TMEG), and the like, but the examples are not limited thereto.

Specifically, the polyamic acid or polyimide may be produced by sequentially dissolving at least one diamine compound represented by Chemical Formula 3 and at least one diamine compound represented by Chemical Formula 4 in a solvent, adding to the solution one or more acid dianhydride compounds represented by Chemical Formula 5 or -6, and reacting them. It is preferable that the reaction of the diamine compound and the acid dianhydride compound is generally performed for 24 hours or so after starting at a temperature range of 0 to 5° C. and until being completed at a temperature range of 10 to 40° C. At this time, it is preferable that the diamine compound and the acid dianhydride compound are mixed with each other at a molar ratio of 1:0.9 to 1:1.1. If the molar ratio of the diamine compound and the acid dianhydride compound is less than 1:0.9, since the molecular weight thereof is very low, the production of a polyimide that has excellent mechanical properties may be difficult. On the contrary, if the molar ratio of the diamine compound and the acid dianhydride compound is more than 1:1.1, since the viscosity is very high, processes that are required in coating and operation may be difficult.

The equivalent of the diamine compound represented by Chemical Formula 4 is preferably 5 to 70% of the total equivalent of diamine compounds contained in the polyamic acid. If the equivalent is less than 5%, the effect of increasing the adhesiveness is not observed. If the equivalent exceeds 70%, the flexibility of film after curing decreases greatly and the adhesiveness is not improved.

As the solvent used for preparing the polyamic acid or polyimide, one or more solvents selected from the group consisting of N-methylpyrrolidinone (NMP), N,N-dimethyl acetamide (DMAc), tetrahydrofuran (THF), N,N-dimethyl formamide (DMF), dimethyl sulfoxide (DMSO), cyclohexane, acetonitrile, and a mixture thereof may be used, but are not limited thereto.

According to another embodiment of the present invention, a photosensitive resin composition comprising a) at least one polymer resin selected from the group consisting of the polyamic acid and the polyimide above, b) a curing accelerator, c) a photocrosslinker, and d) a photoinitiator may be provided.

As described above, using the polyamic acid or polyimide introduced with a functional group selected from the group consisting of the functional groups represented by Chemical Formula 21 to 30 makes it possible to provide a cured film capable of forming a pattern with high resolution and having an excellent developing property in an alkaline aqueous solution, excellent flexibility, excellent adhesion strength, resistance to welding heat, and excellent pressure cooker test (PCT) resistance.

The explanation of the polyamic acid and the polyimide is as set forth above.

The solid content of the polymer resin, which may comprise the polyamic acid, the polyimide, or the mixture thereof, can be determined in consideration of molecular weight, viscosity, and volatility of the polyamic acid comprising a repeating unit represented by Chemical Formula 1 or the polyimide comprising a repeating unit represented by Chemical Formula 2. To achieve the desired properties of a dry film, the solid content is preferably 1 to 20 wt % of the total weight of the photosensitive resin composition.

In addition, the representative examples of b) the curing accelerator comprises a heterocyclic aromatic amine-based compounds, and can be at least one selected from the group consisting of pyridine, triazole, imidazole, quinoline, triazine, and derivatives thereof that may be unsubstituted or substituted with a C3-C12 hydrocarbonyl group.

Specifically, the curing accelerators comprise imidazole, benzoimidazol, 1-methyl imidazole, 2-methyl imidazole, ethylimidazole, 1,2,4-triazole, 1,2,3-triazole, 2-mercaptobenzoxazole, 2,5-dimercapto-1,3,4-tiadiazole, 2-mercaptobenzoxazole, 2,5-dimercapto-1,3,4-tiadiazole, 2-mercapto-4,6-dimethylaminopyridine, 3-hydroxypyridine, 4-hydroxypyridine, 2,4-dimethylpyridine, 4-pyridine methanol, nicotine aldehydeoxime, isonicotinealdehydeoxime, ethylpicolinate, ethyl isopicotinate, 2,2′-bipyridyl, 4,4′-bipyridyl, 3-methylpyridazyl, quinoline, isoquinoline, phenanthridine, 2-mercaptobenzoimidazole, 2-mercaptobenzotriazole, phthalazine, and 1,10-phenanthroline, but are not limited thereto.

b) The curing accelerator is preferably 0.01 to 10 parts by weight based on 100 parts by weight of the polymer resin. If the amount is less than 0.01 parts by weight, the curing degree is not sufficient. If the amount is more than 10 parts by weight, it gives an undesirable effect on the developing property.

The photosensitive resin composition comprises c) a photocrosslinker. Examples of the photocrosslinker comprise a (metha)acrylate-based compound comprising a double bond between carbons. The (metha)acrylate-based compound comprising a double bond between carbons can be a (metha)acrylate-based compound comprising two photopolymerizable double bonds between carbons that comprises a region modified by ethylene oxide (EO) or propylene oxide (PO), or a (metha)acrylate-based compound comprising, in a molecule, at least one photopolymerizable double bond between carbons together and a hydroxyl group or epoxy group in a molecule.

Herein, the term, “(metha)acrylate” is intended to include both the compounds of “methacrylate” and “acrylate”.

The (metha)acrylate-based compound has an excellent compatibility with the polyamic acid or the polyimide. By comprising the (metha)acrylate-based compound in the photosensitive resin composition, an excellent developing property in an alkaline solution and photosensitivity can be obtained. A dry film prepared from the resin composition shows a decreased modulus during heat treatment and an increased flexibility in heat-lamination, improving the property of filling a uneven ( [symbol] ) pattern. Therefore, the dry film can undergo heat-lamination at a relatively low temperature.

The (metha)acrylate-based compound comprising a photopolymerizable double bond between carbons can be at least one selected from the group consisting of the compounds represented by Chemical Formula 7-10.

An example of the (metha)acrylate-based compound comprising two photopolymerizable double bonds between carbons and comprise a region modified by ethylene oxide (EO) or propylene oxide (PO), can be represented by Chemical Formula 7.

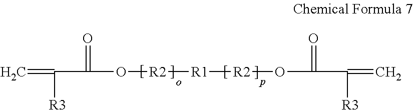

In Chemical Formula 7, R1 may be an aromatic compound comprising two or more benzene rings in a molecule, and examples comprise bisphenol A, bisphenol F, and bisphenol S. Further, R2 may be an ethylene oxide or propylene oxide group, R3 may be a hydrogen or methyl group, and o and p may independently be an integer of 2 or more, providing that o+p may be an integer of 4 to 30.

Examples of the compound represented by Chemical Formula 7 are A-BPE-10, A-BPE 20, A-BPE-30, BPE-500, and BPE-900, which are manufactured by NK Ester; bisphenol A EO-modified (metha)acrylate, bisphenol F EO-modified (metha)acrylate, and PO-modified (metha)acrylate, which are manufactured by Shin Nakamura Chemical Ltd. and SR-480, SR-602, and CD-542, which are manufactured by Stomer.

The acrylate-based compound comprising two or more photopolymerizable double bonds between carbons can be represented by Chemical Formula 8.

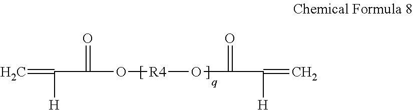

In Chemical Formula 8, R4 may be an organic group consisting of a C1-C10 carbon and hydrogen, or a C1-C10 carbon and oxygen, and preferred examples may be ethyl or propyl, and q may be an integer of 1 to 14.

Examples of the (metha)acrylate-based compound represented by Chemical Formula 8 comprise triethylene glycol diacrylate, neopentyl glycol diacrylate, 1,6-hexanediol diacrylate, 3-methyl-1,5-pentandiol diacrylate, 2-buty-2-ethyl-1,3-propandiol acrylate, 1,9-nonandiol diacrylate, polyethylene glycol diacrylate, PEG#200 diacrylate, PEG#400 diacrylate, and PEG#600 diacrylate, but are not limited thereto.

The (metha)acrylate-based compound comprising at least a photopolymerizable double bond between carbons, together with a hydroxyl group or epoxy group in a molecule, can comprise a compound represented by Chemical Formula 9 or 10.

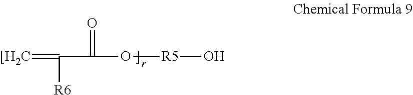

In Chemical Formula 9, R5 may be an organic group consisting of a C2-C8 carbon and hydrogen or a C2-C8 carbon and oxygen, and preferably 2-hydroxyethyl, hydroxypropyl, or phenylglycidylester group. R6 may be hydrogen or a methyl group, and r may be an integer of 1 to 3.

Examples of the compound represented by Chemical Formula 9 are 2-hydroxyethyl methacrylate (HEMA), 2-hydroxypropylmethacrylate, 2-hydroxy acrylate, 2-hydroxypropyl acrylate, 2-hydroxybutyl methacrylate, phenylglycidylester acrylate (Nippon Kayaku, R-128H), 1,6-hexanediol epoxyacrylate (Nippon Kayaku, Kayarad R-167), Ebecryl 9695 (epoxy acrylate oligomer diluted with carbitol acetate), and the like, but are not limited thereto.

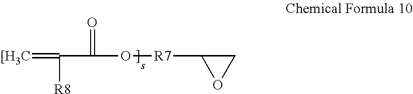

In Chemical Formula 10, R7 may be an organic group consisting of a C1-C6 carbon and hydrogen and preferably a methyl group, R8 may be hydrogen or a methyl group, and s may be an integer of 1 to 3.

Examples of the compound represented by Chemical Formula 10 comprise glycidyl compounds such as glycidyl methacrylate, and NK oligomer EA-1010 and EA-6310 that are manufactured by Shin Nakamura Chemical, but are not limited thereto.

It is preferable that the photosensitive resin composition comprises c) the photocrosslinker in an amount of 30 to 150 parts by weight based on 100 parts by weight of the polymer resin. If the amount of the photocrosslinker is less than 30 parts by weight, the developing property and pattern-filling property may become deteriorated. If it exceeds 150 parts by weight, the heat resistance and mechanical properties such as folding endurance can be decreased.

The photosensitive resin composition comprises d) a photoinitiator. It is preferable that the photosensitive resin composition comprises the photoinitiator in an amount of 0.3 to 10 parts by weight based on 100 parts by weight of the polymer resin. If the photoinitiator is less than 0.3 parts by weight, the photoinitiator becomes to participate in the photocuring reaction less. If it is more than 10 parts by weight, radicals that do not participate in curing can deteriorate the physiochemical properties of the film prepared from the photosensitive resin composition.

Examples of photoinitiator comprise an acetophenone-based compound such as 2-hydroxy-2-methyl-1-phenylpropane-1-on, 1-(4-isopropylphenyl)-2-hydroxy-2-methylpropane-1-on, 4-(2-hydroxyethoxy)-phenyl-(2-hydroxy-2-propyl)ketone, 1-hydroxycyclohexylphenylketone, benzoin methyl ether, benzoin ethyl ether, benzoin isobutyl ether, benzoin butyl ether, 2,2-dimethoxy-2-phenylacetophenone, 2-methyl-(4-methylthio)phenyl-2-morpholino-1-propane-1-on, 2-benzyl-2-dimethylamino-1-(4-morpholinophenyl)-butane-1-on, 2-methyl-1-[4-(methylthio)phenyl]-2-morpholinopropane-1-on and the like; a biimidazole-based compound such as 2,2-bis-(2-chlorophenyl)-4,4′,5,5′-tetraphenyl biimidazole, 2,2′-bis-(o-chlorophenyl)-4,4′,5,5′-tetrakis(3,4,5-trimethoxyphenyl)-1,2′-biimidazole, 2,2′-bis-(2,3-dichlorophenyl)-4,4′,5,5′-tetraphenyl 2,2′-bis-(o-chlorophenyl)-4,4′,5,5′-tetraphenyl-1,2′-biimidazole and the like; a triazine-based compound such as 3-{4-[2,4-bis-(trichloromethyl)-s-triazine-6-yl]phenylthio}propionic acid, 1,1,1,3,3,3-hexafluoroisopropyl-3-{4-[2,4-bis-(trichloromethyl)-s-triazine-6-yl]phenylthio}propionate, ethyl-2-{4-[2,4-bis-(trichloromethyl)-s-triazine-6-yl]phenylthio}acetate, 2-epoxyethyl-2-{4-[2,4-bis-(trichloromethyl)-s-triazine-6-yl]phenylthio}acetate, cyclohexyl-2-{4-[2,4-bis-(trichloromethyl)-s-triazine-6-yl]phenylthi-o}acetate, benzyl-2-{4-[2,4-bis-(trichloromethyl)-s-triazine-6-yl]phenylthi-o}acetate, 3-{chloro-4-[2,4-bis-(trichloromethyl-s-triazine-6-yl]phenylthio}propionic acid, 3-{4-[2,4-bis-(trichloromethyl-s-triazine-6-yl]phenylthio}propionamide, 2,4-bis-(trichloromethyl)-6-p-methoxystyryl-s-triazine, 2,4-bis-(trichloromethyl)-6-(1-p-dimethylaminophenyl)-1,3-butadienyl-s-triazine, 2-trichloromethyl-4-amino-6-p-methoxystyryl-s-triazine and the like; and an oxime-based compound such as CGI-242 and CGI-124 manufactured by Chiba, Co., Ltd. in Japan. However, the photoinitiator cannot be limited to the examples.

As an additional component of the photosensitive resin composition, to accelerate radial generation, a photosensitizer may be used in the photosensitive resin composition in an amount of 0.01 to 10 parts by weight, or more preferably 0.1 to 5 parts by weight based on 100 parts by weight of the polymer resin. If the photosensitizer is less than 0.01 parts by weight, the curing is not sufficient. If it exceeds 10 parts by weight, the photosensitizing effect cannot be achieved or it gives an undesirable effect on the developing property.

Examples of the photosensitizer comprise benzophenone-based compounds such as benzophenone, 4,4-bis-(dimethylamino)benzophenone, 4,4-bis-(diethylamino)benzophenone, 2,4,6-trimethylaminobenzophenone, methyl-o-benzoylbenzoate, 3,3-dimethyl-4-methoxybenzophenone, or 3,3,4,4-tetra(t-butylperoxycarbonyl)benzophenone; fluorenone-based compounds such as 9-fluorenone, 2-chloro-9-fluorenone, or 2-methyl-9-fluorenone; thioxanthone-based compounds such as thioxanthone, 2,4-diethyl thioxanthone, 2-chloro thioxanthone, 1-chloro-4-propyloxy thioxanthone, isopropylthioxanthone, or diisopropyl thioxanthone; xanthone-based compounds such as xanthone or 2-methylxanthone; anthraquinone-based compounds such as anthraquinone, 2-methyl anthraquinone, 2-ethyl anthraquinone, t-butyl anthraquinone, or 2,6-dichloro-9,10-anthraquinone; acridine-based compounds such as 9-phenylacridine, 1,7-bis-(9-acridinyl)heptane, 1,5-bis-(9-acridinylpentane), or 1,3-bis-(9-acridinyl)propane; dicarbonyl-based compounds such as 1,7,7-trimethyl-bicyclo[2,2,1]heptan-2,3-dione, or 9,10-phenanthrene quinone; phosphine oxide-based compounds such as 2,4,6-trimethylbenzoyl eiphenylphosphine oxide or bis-(2,6-dimethoxybenzoyl)-2,4,4-trimethylpentyl phosphine oxide; benzoate-based compounds such as methyl-4-(dimethylamino)benzoate, ethyl-4-(dimethylamino)benzoate, or 2-n-butoxylethyl-4-(dimethylamino)benzoate; amino synergist compound such as 2,5-bis-(4-diethylaminobenzal)cyclopentanone, 2,6-bis-(4-diethylaminobenzal)cyclohexanone, or 2,6-bis-(4-diethylaminobenzal)-4-methyl-cyclopentanone; coumarine-based compounds such as 3,3-carbonylvinyl-7-(diethylamino)coumarine, 3-(2-benzothiazolyl)-7-(diethylamino)coumarine, 3-benzoyl-7-(diethylamino)coumarine, 3-benzoyl-7-methoxy-coumarine, or 10,10-carbonyl-bis-[1,1,7,7-tetramethyl-2,3,6,7-tetrahydro-1H,5H,11H—C1-benzopyrano[6,7,8ij-quinolizine-11-on; chalcone-based compounds such as 4-diethylamino chalcone, 4-azidbenzalacetophenone; 2-benzolymethylene; and 3-methyl-b-naphthothiazoleine.

The photosensitive resin composition may comprise a phosphorus-based flame retardant. The phosphorus-based flame retardant can contain phosphorus atoms and a (metha)acrylate group in its chemical structure as represented by Chemical Formula 11, a phosphorus-based compound represented by Chemical Formula 12, a compound having an epoxy group, and an additive compound of a (metha)acrylate compound and a phosphorus-based compound represented by Chemical Formula 12 or a compound having an epoxy group.

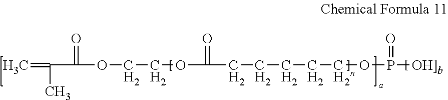

In Chemical Formula 11, n is an integer of 0≦n<10, and each of a and b is an integer with the proviso that a+b is 3.

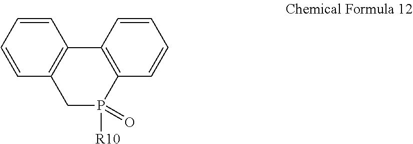

In Chemical Formula 12, R10 is

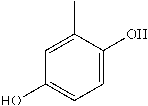

or hydrogen.

The phosphorus-based flame retardant may be compatible to use with the photosensitive resin composition and provides it with flame retardancy. On the basis of the content of phosphorous atoms, the flame retardant can be contained in the photosensitive resin composition at 0.1 to 20 wt %, or more preferably 0.5 to 5 wt % of the total solid weight of other components except for the polymer resin. If the content is less than 0.1 wt % of the total solid weight of the photosensitive resin composition, a sufficient flame retardant property cannot be achieved. If it exceeds 20wt % of the total solid weight of the photosensitive resin composition, the mechanical properties of the film such as the developing property can be deteriorated.

Examples of the flame retardant comprise compounds represented by Chemical Formula 11 such as 2-hydroxyethyl methacrylate phosphate (trademark: KAYAMER PM-2) and 2-hydroxyethyl methacrylate caprolactone phosphate (trademark; KAYAMER PM-21). Representative examples of the compounds represented by Chemical Formula 11 are 10-(2,5-dihydroxyphenyl)-10H-9-oxa-10-phospha-phenantbrene-10-oxide (HCA-HQ) and 9,10-dihydro-9-oxa-10-phospha-phenantbrene-10-oxide (HCA), and the additive compounds of the compounds represented by Chemical Formula 11 and the compound having at least one (metha)acryl group in a molecule.

The compounds having a (metha)acryl group in a molecule are one or more compounds selected from the group consisting of a 2-hydroxyethyl(metha)acrylate-based compound, a benzyl(metha)acrylate-based compound, a phenoxypolyethylene(metha)acrylate-based compound, a methoxypolypropylene glycol(metha)acrylate-based compound, a 2-hydroxypropyl(metha)acrylate-based compound, (metha)acryloxyethyl hydrogenphthalate, a 1,6-hexandiol(metha)acrylate-based compound, an ethandiol(metha)acrylate-based compound, a methylenebis-(metha)acrylate-based compound, neopentylglycoldi(metha)acrylate, a 2-hydroxypropandioldi(metha)acrylate-based compound, an isopropyldioldi(metha)acrylate-based compound, and an isopropyleneglycoldi(metha)acrylate-based compound, but are not limited thereto.

The organic solvent used in the photosensitive resin composition can be any one being capable of easily dissolving a) polymer resin, b) a curing accelerator, c) a photocrosslinker, and d) a photoinitiator, and preferably, one that is easily dried in the coating process. The amount of organic solvent is preferably 300 to 700 parts by weight, based on 100 parts by weight of the polymer resin in the photosensitive resin composition.

The organic solvent can preferably be a polar aprotic organic solvent in the aspect of solubility. Specific examples of the organic solvent comprise at least one selected from the group consisting of N-methyl-2-pyrrolidone, N-acetyl-2-pyrrolidone, N-benzyl-2-pyrrolidone, N,N-dimethylformamide, N,N-dimethylacetamide, dimethyl sulfoxide, hexanemethylphosphortriamide, N-acetyl-∈-caprolactam, dimethylimidazolidoneimidazolidinone, diethylene glycol dimethylether, triethyleneglycoldimethylether, γ-butyrolactone, dioxane, dioxolane, tetrahydrofuran, chloroform, and chloromethylene, but are not limited thereto.

The composition further comprises an additive selected from the group consisting of a defoaming agent, a leveling agent, and an anti-gelling agent, for ease of coating or curing or for improving other physichochemical properties on an as-need basis.

In another embodiment of the present invention, a dry film prepared by using the photosensitive resin composition is provided.

The dry film may be prepared by coating the photosensitive resin composition on a support and drying using a known method. The photosensitive resin composition layer can be delaminated from the support, and preferably the support has excellent optical permeability. In addition, it is preferable that the support provides good flatness.

As specific examples of the support, there may be various plastic films such as polyethylene terephthalate, polyethylene naphthalate, polypropylene, polyethylene, cellulose tri-acetate, cellulose di-acetate, poly(metha)acrylic acid alkyl ester, a poly(metha)acrylic acid ester copolymer, polyvinyl chloride, polyvinyl alcohol, polycarbonate, polystyrene, cellophane, a polyvinyl chloridene copolymer, polyamide, polyimide, a vinyl chloride vinyl acetate copolymer, polytetrafluoroethylene, polytrifluoroethylene, and the like. In addition, a combination material consisting of two or more plastic films thereof may be used, and the polyethylene terephthalate film having excellent optical permeability is particularly preferable. The thickness of the support is preferably in the range of 5 to 150 μm, and more preferably 10 to 50 μm.

The coating method of the photosensitive resin composition is not particularly limited, and for example, methods such as a spray method, a roll coating method, a rotation coating method, a slit coating method, a compression coating method, a curtain coating method, a die coating method, a wire bar coating method, and a knife coating method may be used. Drying of the photosensitive resin composition varies according to the components, the organic solvent, and the content ratio, but it is preferable that drying is carried out at 60 to 100° C. for 30 sec to 15 min.

The thickness of the dry film after drying and curing, is in the range of preferably 5 to 95 μm and more preferably 10 to 50 μm. If the film thickness of the dry film is less than 5 μm, the insulating property is not good, and if the film thickness is more than 95 μm, the resolution may be decreased.

According to another embodiment of the present invention, a circuit board comprising the dry film may be provided.

Examples of the circuit board comprise a multilayered print wiring board, a flexible circuit board, and a soft circuit board, but are not limited thereto.

In the circuit board comprising the dry film, the dry film prepared above is multilayered on a circuit-forming surface by using a vacuum lamination method at 60 to 90° C. after pre-laminating the dry film using a plane compression method or a roll compression method at a temperature in the range of 25 to 50° C. The pattern may be formed by exposing the multilayered dry film using a photomask in order to form a fine hole or a fine width line. The amount of UV exposure varies depending on the kind of light source and the thickness of the film used, but in general, the exposure amount is preferably in the range of 100 to 1,200 mJ/cm², and more preferably 100 to 400 mJ/cm². Electronic rays, ultraviolet(UV) rays, X-rays, and the like, can be used as active rays, and preferably the UV rays may be used. A high pressure mercury lamp, a low pressure mercury lamp, a halogen lamp, and the like may be used as a light source.

For developing after the exposure, a dipping method is generally used to dip it in a developing solution. An alkalin aqueous solution such as a sodium hydroxide aqueous solution and a sodium carbonate aqueous solution is used as the developing solution. After the development by using the alkalin aqueous solution, water washing is performed. Then, along the pattern obtained from the development through a heat treatment process, the polyamic acid is changed into polyimide. Preferably, the temperature required in the heat treatment is in the range of 150 to 230° C. that is required for imidization. At this time, it is more effective to increase the heating temperature continuously through 2 to 4 steps using an appropriate temperature profile, but in some cases, the curing may be carried out at a constant temperature. By carrying out the above process, the circuit board comprising the dry film can be obtained.

Another embodiment of the present invention provides a laminate body for a semiconductor comprising the dry film as a protective film or an interlayer insulating film.

As the composition and the production method of the laminate body for a semiconductor, a commonly known technology in the art may be used, except that the dry film according to the present invention is used as a protective film or an interlayer insulating film.

### EFFECTS OF THE PRESENT INVENTION

According to the embodiments of the present invention, a novel polyamic acid and polyimide are provided.

In addition, according to the embodiments of the present invention, there are provided the photosensitive resin composition that enables forming a pattern with high resolution, an excellent developing property using an alkaline aqueous solution and excellent flexibility, adhesiveness, soldering heat resistance and resistance measured by the Pressure Cooker Test.

### BRIEF DESCRIPTION OF THE DRAWINGS

FIG. 1 is a schematic drawing of a photomask used for evaluating the developing property of the dry film of the present invention.

FIG. 2 is an NMR graph of a polyamic acid prepared according to the present invention

### WORKING EXAMPLES OF THE INVENTION

Hereinafter, the functions and effects of the present invention are explained in more detail with reference to the following examples. However, the examples are provided only for exemplifying the present invention, and should not be interpreted as limiting the scope of the present invention in any manner.

### Example 1

### Preparation of Polyamic Acid and Photosensitive Resin Composition

While letting nitrogen flow into a four-neck round bottom flask installed with a thermometer, an agitator, a nitrogen input port and a powder dispensing funnel, 190 g of N,N-dimethyl acetamide (DMAc) was added to 7.94 g of 4,4′-oxydianiline (4,4′-ODA), 27.02 g of 1,3-bis-(4-aminophenoxy)benzene (TPE-R)), and 3.82 g of 2′-(methacryloyloxy)ethyl 3,5-diaminobenzoate in the four-neck round bottom flask, and dissolve them completely by agitating. The solution was cooled to 15° C. or lower, and 18g of 4,4′-oxydiphthalic anhydride (ODPA) was slowly added. The solution was agitated at 5° C. for 25 hours to obtain a polyamic acid varnish.

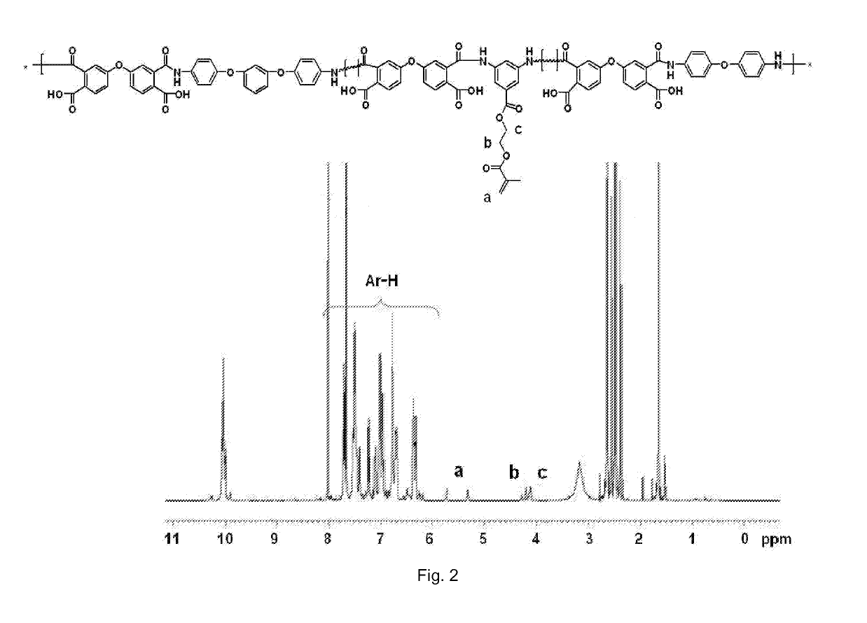

The viscosity of the produced polyamic acid was 3200 cps. After the product polymer was obtained by precipitation, it was confirmed by NMR analysis that 2′-(methacryloyloxy)ethyl 3,5-diaminobenzoate was inserted into polyamic acid. The NMR graph is shown in FIG. 2.

To 100 g of the polyamic acid varnish thus obtained, 15 g of A-BPE-20 (trade name, manufactured by Shin Nakamura Chemical Co.) and 15 g of Kayarad R-128H (manufactured by Nippon Kayahu Co., Ltd) as a photocrosslinker; 1.5 g of KAYAMER PM-2 PM-2 (manufactured by Nippon Kayahu Co., Ltd) as a flame retardant; and 0.3 g of 2,2-dimethoxy-2-phenylacetophenone (trademark: Irgacure 651, CIBA) and 0.2 g of 2-benzyl-2-dimethylamino-1-(4-morpholynophenyl)-1-butanone (trademark: Irgacure 369, manufactured by Ciba), and 0.9 g of 1,2,4-triazole as a photoinitiator, were added to produce a photosensitive resin composition.

### Examples 2 to 5 and Comparative Example 1

Except that the components and their composition in Table 1 were used, polyamic acid and photosensitive resin compositions were prepared according to the same method as in Example 1.

TABLE 1

| | ODPA (g) | 4,4′-ODA (g) | TPE-R (g) | HEMA-DA (g) |
|---|---|---|---|---|
| Example 2 | 43.17 | 7.54 | 25.64 | 3.68 |
| Example 3 | 43.19 | 7.11 | 24.20 | 5.52 |
| Example 4 | 43.17 | 6.69 | 22.80 | 7.36 |
| Example 5 | 43.18 | 5.02 | 17.09 | 14.72 |
| Comparative | 43.17 | 8.36 | 28.48 | 0 |
| Example 1 | | | | |

ODPA: 4,4′-oxydiphthalic anhydride
4,4′-ODA: 4,4′-oxydianiline
TPE-R: 1,3-bis-(4-aminophenoxy)benzene
HEMA-DA: 2′-(methacrloyloxy)ethyl 3,5-diaminobenzoate

### EXPERIMENTAL EXAMPLE

### Evaluation of Film Physicochemical Properties

The photosensitive resin compositions obtained in Examples 1 to 5 and Comparative Example 1 were coated on a polyethyleneterephthalate (PET) film using a doctor blade in a thickness of 71 μm, and dried in oven at 80° C. for 15 minutes to obtain dry films with a thickness of 25 μm.

### Experimental Example 1

### Transparency

The transparency of the dry films was observed by the naked eye, and the results are shown in Table 2.

### Experimental Example 2

### Processability

The dry films were put on a cooper laminate of 2 Copper Clad Laminate product where the pattern for the MIT test was formed, and laminated by using a vacuum laminator MVLP-500/600 (MEIKI) for 30 seconds after providing a pressure at 70° C. for 30 seconds. Then, the processability from the lamination step to developing step was tested and the results are shown in Table 2.

### Experimental Example 3

### Pattern Filling

The dry films obtained after the processability test according to Experimental Example 2 was cured in an oven at 220° C. under a nitrogen atmosphere for 1 hour. Whether a void was formed between the patterns was evaluated with an electronic microscope and the results are shown in Table 2.

### Experimental Example 4

### Developing Property

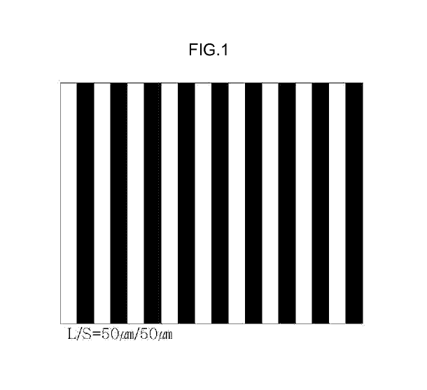

The dry films obtained after the processability test according to Experimental Example 2 was subjected to vacuum lamination on the copper clad. The photomask shown in FIG. 1 was put on the dry film, exposed at 350 mJ/cm² of UV, and subjected to spray development by using a 1 wt % sodium carbonate aqueous solution. The developing time was measured by using the pitch of L/S=50 μm/50 μm as the same as the photomask, and the results are shown in Table 2.

### Experimental Example 5

### Surface Roughness

The surface of the dry films obtained after the developing property test according to Experimental Example 4 was observed by the naked eye, and the result of surface roughness is shown in Table 2.

### Experimental Example 6

### Pencil Hardness

The dry films was laminated on a glass plate at 125° C., exposed to 350 mJ/cm² of UV radiation, and developed by a Na₂CO₃ 1 wt % aqueous solution. The developed dry film was imidized by heating in an oven at 200° C. for 60 minutes to produce the dry film with a thickness of 20 μm. According to the ISO 15184 measuring method, the pencil hardness was tested and is shown in Table 2.

### Experimental Example 7

### Adhesion Strength

The dry films obtained after the developing property test according to Experimental Example 4 was tested for adhesion strength by using a universal test machine (UTM), and the results are shown in Table 2.

### Experimental Example 8

### Soldering Heat Resistance

The dry films obtained after the developing property test according to Experimental Example 4 was immersed 6 times in a solder pot at 288±5° C. for 10 seconds while arranging the film surface upward according to the JISC 6481 method. Then, aberrations of the dry film were detected by an eye inspection and the results are shown in Table 2.

### Experimental Example 9

### Soldering Heat Resistance after PCT (Pressure Cooker Test)

The dry films obtained after the developing property test according to Experimental Example 4 was held at 121° C., 2 atm, with saturated water vapor of 100% RH for 30 minutes and taken out. The film was immersed in a solder pot at 288±5° C. for 60 seconds while arranging the film surface upward. Then, aberrations of the dry film were detected by eye inspection and the results are shown in Table 2.

TABLE 2

| | | | | | | Comparative |
|---|---|---|---|---|---|---|
| | Example 1 | Example 2 | Example 3 | Example 4 | Example 5 | Example 1 |
| Experimental | Δ | ◯ | ◯ | ⊚ | ⊚ | X |
| Example 1 | | | | | | |
| Experimental | ◯ | ⊚ | ⊚ | ◯ | ◯ | ◯ |
| Example 2 | | | | | | |
| Experimental | ◯ | ⊚ | ⊚ | ◯ | ◯ | Δ |
| Example 3 | | | | | | |
| Experimental | 80 sec | 70 sec | 56 sec | 56 sec | 48 sec | 90 sec |
| Example 4 | | | | | | |
| Experimental | Δ | ◯ | ◯ | ◯ | ◯ | X |
| Example 5 | | | | | | |
| Experimental | 3H | 3H | 3H | 3H | 3H | 4H |
| Example 6 | | | | | | |
| Experimental | 220 g/cm | 282 g/cm | 195 g/cm | 171 g/cm | 150 g/cm | 172 g/cm |
| Example 7 | | | | | | |
| Experimental | normal | normal | normal | normal | normal | normal |
| Example 8 | | | | | | |
| Experimental | normal | normal | normal | normal | normal | Partly Detach |
| Example 9 | | | | | | |

□: very good.
◯: good.
□: bad.
X: very bad.

As shown in Table 2, compared with the dry film of Comparative Example 1 where the polymer resin was a polyamic acid without a functional group derived from HEMA-DA, it was confirmed that the dry film prepared from the photosensitive resin in the examples showed relatively high transparency, processability, pattern filling property, developing property, and surface smoothness. In addition, the dry film of the examples represented excellent adhesion strength, soldering heat resistance, and post-PCT soldering heat resistance, and delamination from the support was not observed.

What is claimed is:

1. A polyamic acid comprising a repeating unit represented by Chemical Formula 1: 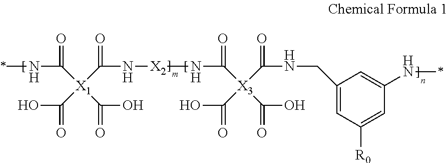
wherein, in Chemical Formula 1,
n is from 5 mol % or more to less than 70 mol %,
m is from 30 mol % or more to less than 95 mol %,
X₁ and X₃ are the same or different and are independently a tetravalent organic group comprising an aromatic ring structure,
X₂ is a divalent organic group comprising an aromatic ring structure, and
R₀ is a functional group selected from the group consisting of functional groups represented by Chemical Formulae 21 to 30:

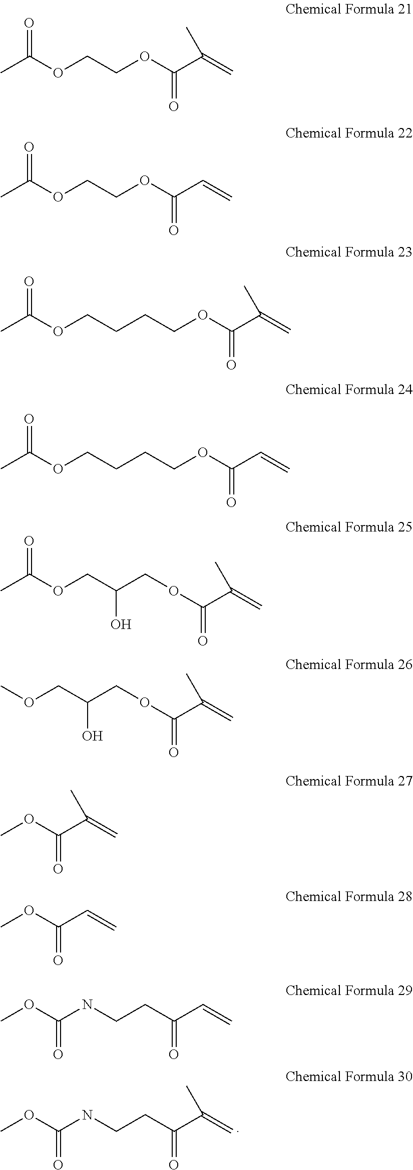

2. The polyamic acid of claim 1,
wherein X₁ and X₃ in Chemical Formula 1 are the same or different and are independently a tetravalent organic group comprising a group represented by Chemical Formula 31 or 32: 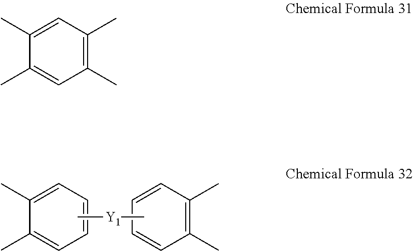
wherein, in Chemical Formula 32, Y₁ is a single bond, —O—, —CO—, —S—, —SO₂—, —C(CH₃)₂—, —C(CF₃)₂—, —CONH, —(CH₂)n₁-, —O(CH₂)n₂O—, or —COO(CH₂)n₃OCO—, and n₁, n₂, and n₃ are independently an integer of 1 to 5.

3. The polyamic acid of claim 1,
wherein X₂ in Chemical Formula 1 is a divalent organic group selected from the groups represented by Chemical Formula 33 to 36: 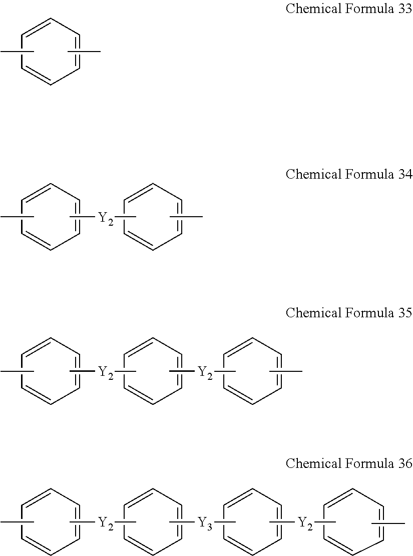
wherein, in Chemical Formula 34 to 36, Y₂ and Y₃ are the same or different and are independently a single bond, —O—, —CO—, —S—, —SO₂—, —C(CH₃)₂—, —C(CF₃)₂—, —CONH, —(CH₂)n₁-, —O(CH₂)n₂O—, or —COO(CH₂)n₃OCO—, and n₁, n₂, and n₃ are independently an integer of 1 to 5.

4. The polyamic acid of claim 1, wherein the polyamic acid has a number-average molecular weight of 5,000 to 300,000.

5. A polyimide comprising a repeating unit represented by Chemical Formula 2: 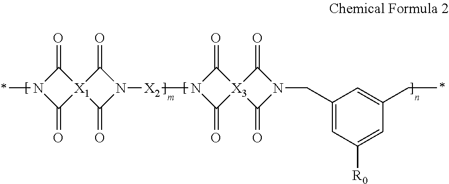
wherein, in Chemical Formula 2,
n is from 5 mol % or more to less than 70 mol %,
m is from 30 mol % or more to less than 95 mol %,
X1 and X3 are the same or different and are independently a tetravalent organic group comprising an aromatic ring structure,
X2 is a divalent organic group comprising an aromatic ring structure, and
R0 is a functional group selected from the groups represented by Chemical Formulae 21 to 30:

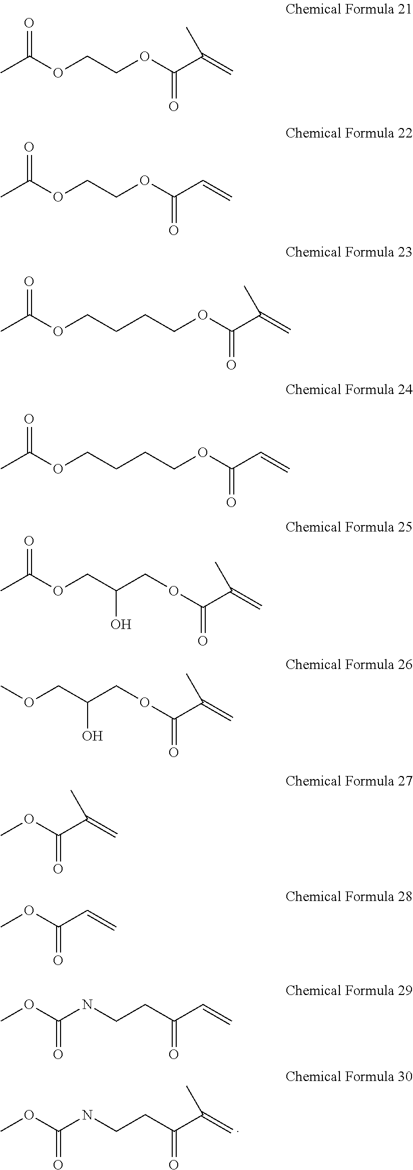

6. A photosensitive resin composition comprising:
a) at least one polymer resin selected from the group consisting of the polyamic acid of claim 1 and the polyimide of claim 5;
b) a curing accelerator;
c) a photocrosslinker; and
d) a photoinitiator.

7. The photosensitive resin composition of claim 6, wherein the solid content of the a) polymer resin is 1 to 20 wt % of the total weight of the photosensitive resin composition.

8. The photosensitive resin composition of claim 6, wherein the b) curing accelerator is a heterocyclic aromatic amine.

9. The photosensitive resin composition of claim 6, wherein the b) curing accelerator is comprised in an amount of 0.01 to 10 parts by weight based on 100 parts by weight of the polymer resin in the photosensitive resin composition.

10. The photosensitive resin composition of claim 6, wherein the c) photocrosslinker is a (metha)acrylate-based compound comprising a double bond between carbons.

11. The photosensitive resin composition of claim 10, wherein the (metha)acrylate-based compound comprising a double bond between carbons is at least a compound selected from the group consisting of the compounds represented by Chemical Formula 7 to 10: 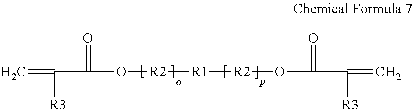
wherein, in Chemical Formula 7,
R1 is an aromatic group comprising two or more benzene rings in a molecule,
R2 is ethylene oxide or a propylene oxide group,
R3 is hydrogen or a methyl group, and
o and p are independently an integer of 2 or larger, with the proviso that o+p is an integer of 4 to 30; 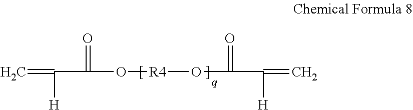
wherein, in Chemical Formula 8,
R4 is an organic group consisting of a C1-C10 carbon and hydrogen, or a C1-C10 carbon and oxygen, and
q is an integer of 1 to 14; 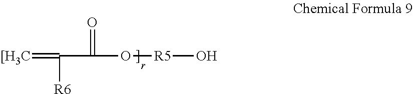
wherein, in Chemical Formula 9,
R5 is an organic group consisting of a C2-C8 carbon and hydrogen or a C2-C8 carbon and oxygen,
R6 is hydrogen or a methyl, and
r is an integer of 1 to 3; 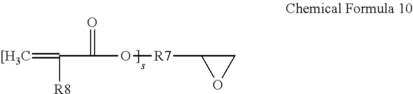
wherein, in Chemical Formula 10,
R7 is an organic group consisting of a C1-C6 carbon and hydrogen,
R8 is hydrogen or a methyl, and
s is an integer of 1 to 3.

12. The photosensitive resin composition of claim 6, wherein the c) photocrosslinker is comprised in an amount of 30 to 150 parts by weight based on 100 parts by weight of the polymer resin in the photosensitive resin composition.

13. The photosensitive resin composition of claim 6, wherein the d) photoinitiator is at least a compound selected from the group consisting of an acetophenone-based compound, a biimidazole-based compound, a triazine-based compound, and an oxime-based compound.

14. The photosensitive resin composition of claim 6, wherein the d) photoinitiator is comprised in an amount of 0.3 to 10 parts by weight based on 100 parts by weight of the polymer resin in the photosensitive resin composition.

15. A dry film comprising the photosensitive resin composition of claim 6.

16. A circuit board manufactured by using the dry film of claim 15.

17. The circuit board of claim 16, wherein the circuit board is a multilayered print wring board, a flexible circuit board or soft circuit board.

18. The circuit board of claim 17, wherein the circuit board is a laminated body for a semiconductor comprising the dry film of claim 15.
